(19) United States
(12) Patent Application Publication
(10) Pub. No.: US 2014/0182905 A1
(43) Pub. Date: Jul. 3, 2014

(54) PRINTED CIRCUIT BOARD AND SURFACE TREATMENT METHOD OF PRINTED CIRCUIT BOARD

(71) Applicant: Samsung Electro-Mechanics Co., Ltd., Suwon (KR)

(72) Inventors: Kyung Moo HAR, Suwon (KR); Chang Bae LEE, Yongin (KR); Jin Gu KIM, Suwon (KR); Young Do KWEON, Suwon (KR)

(73) Assignee: Samsung Electro-Mechanics Co., Ltd., Suwon (KR)

(21) Appl. No.: 14/143,475

(22) Filed: Dec. 30, 2013

(30) Foreign Application Priority Data
Dec. 31, 2012 (KR) 10-2012-0157887

(51) Int. Cl. H05K 13/00; H05K 1/09

(52) U.S. Cl. CPC H05K 13/00; H05K 1/09
USPC 174/257; 228/219

(57) ABSTRACT

Disclosed herein are a printed circuit board including a copper foil layer surface treated with Pb-free solder having the same height as that of a solder resist, and a surface treatment method of the printed circuit board.

According to the present invention, the surface treatment of the package board or interposer board having an ultra-fine pitch (300 μm or less) may be easily implemented by a cheap process. In addition, the surface treatment of the printed circuit board may be eco-friendly performed by using the Pb-free solder, and it may be easy to surface treat the package board or interposer board based on the organic material sensitive to a high temperature.

### CROSS REFERENCE(S) TO RELATED APPLICATIONS

This application claims the benefit under 35 U.S.C. Section 119 of Korean Patent Application Serial No. 10-2012-0157887, entitled “Printed Circuit Board and Surface Treatment Method of Printed Circuit Board” filed on Dec. 31, 2012, which is hereby incorporated by reference in its entirety into this application.

### BACKGROUND OF THE INVENTION

1. Technical Field

The present invention relates to a printed circuit board and a surface treatment method of the printed circuit board.

2. Description of the Related Art

The trend of the electronic industry is to cheaply manufacture a product capable of implementing lightness, miniaturization, a high speed, multi-functions, and high performance and having high reliability. Therefore, in accordance with the trends toward a rapid increase in the number of input/output units (I/O) of integrated circuit (IC), a technology for high-density packaging has been demanded. One of the important technologies capable of high-density packaging is a system in package (SIP) technology.

In the SIP technology, a fine pitch technology for a package board does not appropriately cope with a fine pitch due to the rapid increase in the I/O of the IC. Therefore, an interposer has been prominent as a board capable of implementing electrical interconnection between the IC and the package board.

In the case of this interposer board, the board has a significantly small pitch and a pad size, and also has a significantly thin thickness due to characteristics of the board. In addition, in the case of the interposer based on an organic material, a severe damage may be generated by heat at the time of high temperature process. Particularly, the interposer board or the package board as described above has a significantly small pad size and pitch. Therefore, in the case of the special board as described above, in a surface treatment method according to the related art, various problems may be generated.

A surface treatment method of a printed circuit board (PCB) is a method of coating a copper exposed portion in the PCB in order to prevent a copper wire circuit of the printed circuit board (PCB) from being oxidized and facilitate connection with mounted components. In this surface treatment method of a PCB, a copper exposed portion of a copper foil layer opened in order to disposed the IC and electronic components on the surface of the PCB is coated, such that the oxidation of the copper exposed portion may be prevented, and adhesion force of the IC or electronic components at the time of surface-mounting of the electronic component may be increased.

Examples of the surface treatment method of a PCB as described above include a hot air solder leveling (HASL) method, an electroless gold plating method, an organic solderability preservative (OSP) method, an electroless tin (Sn) plating method, an electroless silver (Ag) plating, an electroless palladium (Pd) plating method, and the like.

Among them, the HASL method is a method of coating the copper foil layer with a solder using wettability due to surface tension of the solder by passing a PCB product on a liquid solder coater having a temperature of a melting point or more. However, since the PCB is not uniformly coated with the solder in this method, it is impossible to apply the fine pitch, and in the case in which the solder is coated on an undesired portion, it may be difficult to finely remove only the portion.

### RELATED ART DOCUMENT

### Patent Document

(Patent Document 1) Korean Patent Laid-Open Publication No. 2006-091198

### SUMMARY OF THE INVENTION

An object of the present invention is to provide a printed circuit board including a copper foil layer surface treated using a Pb-free solder.

Another object of the present invention is to provide a surface treatment method of a printed circuit board capable of stably performing surface treatment on a board pad having an ultra-fine pitch size (100 μm or less) by maximizing advantages of a throughput in an HASL treatment method according to the related art.

According to an exemplary embodiment of the present invention, there is provided a printed circuit board including a copper foil layer surface treated with a Pb-free solder having the same height as that of a solder resist.

The Pb-free solder may contain Sn as a main component and additionally contains at least one kind selected from Bi, In, Ag, Zn, and Cu.

The Pb-free solder may have a melting point of 110 to 220° C.

The printed circuit board may be a package board or an interposer board.

The copper foil layer may be a fine pitch copper pad having a pad size of 200 μm or less and a pad pitch of 300 μm or less.

According to another exemplary embodiment of the present invention, there is provided a surface treatment method of a printed circuit board, the surface treatment method including: screening an open pad except for a copper foil layer with a mask; applying Pb-free solder powder onto the copper foil layer; removing the mask; lumping the Pb-free solder powder by ref lowing the Pb-free solder powder applied onto the copper foil layer; and planarizing the lumped Pb-free solder powder by a hot air flux spray (HAFS) method.

The copper foil layer may be a fine pitch copper pad having a pad size of 200 μm or less and a pad pitch of 300 μm or less.

The Pb-free solder powder may contain Sn as a main component and additionally contain at least one kind selected from Bi, In, Ag, Zn, and Cu.

The Pb-free solder powder may have a melting point of 110 to 220° C.

An average particle size of the Pb-free solder powder may be a half or less of a diameter of the open pad.

The reflowing may be performed at a temperature higher than a melting point of the Pb-free solder powder.

### BRIEF DESCRIPTION OF THE DRAWINGS

FIG. 1 is a view showing a surface treatment process of a printed circuit board according to an exemplary embodiment of the present invention, and

FIG. 2 is a result obtained by measuring a size of a copper foil layer pad of a printed circuit board including a copper foil layer surface treated according to the exemplary embodiment of the present invention.

### DESCRIPTION OF THE PREFERRED EMBODIMENTS

Hereinafter, the present invention will be described in more detail.

Terms used in the present specification are used in order to describe specific exemplary embodiments rather than limiting the present invention. Unless explicitly described to the contrary, a singular form includes a plural form in the present specification. Terms “comprise” and variations such as “comprise” and/or “comprising” used in the present specification will imply the existence of stated shapes, numbers, steps, operations, elements, and/or groups thereof, but does not include the exclusion of any other shapes, numbers, steps, operations, elements, and/or groups thereof.

The present invention relates to a printed circuit board and a surface treatment method of a printed circuit board.

The printed circuit board (PCB) according to an exemplary embodiment of the present invention includes a copper foil layer surface treated using a Pb-free solder having the same height as that of a solder resist.

In the present invention, the surface treatment of a copper exposed portion of the PCB for preventing a copper wire circuit of the PCB from being oxidized and facilitating connection with mounted components is performed by using the Pb-free solder, wherein the copper foil layer surface treated with the Pb-free solder has the same height as that of the solder resist.

When the copper foil layer surface treated with the Pb-free solder has the same height as that of the solder resist, formation of a dimple on a pre-solder at the time of formation of a bump may be prevented, thereby making it possible to prevent interconnection void between a chip and the board.

The Pb-free solder according to the present invention contains at least one kind selected from Bi, In, Ag, Zn, and Cu in addition to Sn as a main component. For example, the Pb-free solder may be made of SnCu, SnZn, SnBi, SnAg, SnAgCu, or the like, but is not limited thereto.

The surface treatment method according to the present invention, which uses the Pb-free solder that does not contain a lead (Pb) component, may implement the surface treatment of the printed circuit board by an eco-friendly process and be easily used for surface treatment of a package board or an interposer board based on an organic material sensitive to a high temperature.

In addition, as the Pb-free solder, a lower melting point solder having a melting point of 110 to 220° C. may be preferable in that thermal stress applied to an organic board may be decreased.

Further, the Pb-free solder according to the exemplary embodiment of the present invention may have an average particle size of a half or less of a diameter of an open pad. That is, it may be preferable that the size of the Pb-free solder is adjusted so as to appropriately pre-solder a copper pad.

In addition, the printed circuit board according to the present invention may be the package board or the interposer board, but is not particularly limited thereto. Any board may be used as long as the board has a fine pitch size.

As the copper foil layer, a fine pitch copper pad having a pad size of 200 μm or less and a pad pitch of 300 μm or less may be preferably used.

Further, the surface treatment of a printed circuit board according to the exemplary embodiment of the present invention may be performed by screening an open pad except for a copper foil layer with a mask; applying Pb-free solder powder onto the copper foil layer; removing the mask; lumping the Pb-free solder powder by ref lowing the Pb-free solder powder applied onto the copper foil layer; and planarizing the lumped Pb-free solder powder by a hot air flux spray (HAFS) method.

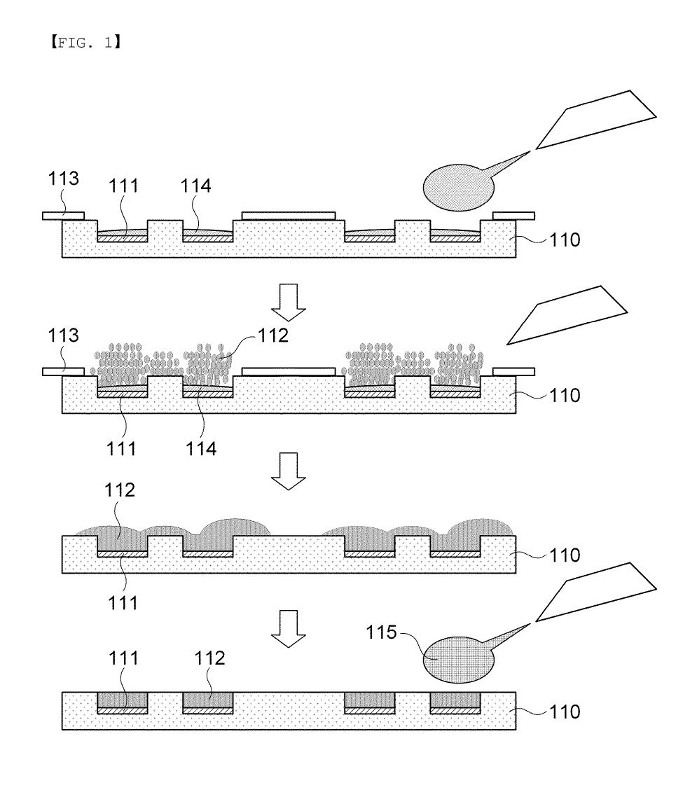

More specifically, a surface treatment process of a printed circuit board according to the exemplary embodiment of the present invention will be described with reference to FIG. 1.

First, a powder type Pb-free solder 112 is used so that copper pads 111 having a fine pitch A (pad size of 200 μm or less, pad pitch of 300 μm or less) of an interposer board 110 may be appropriately pre-soldered. In this case, a sufficient amount of the Pb-free solder powder 112 may be filled in the pad by having a size that is a half or less of a diameter of open pads (the diameter of the open pad is less than 100 μm).

In addition, in order to allow an unnecessary portion of the board 110 not to be smeared with the Pb-free solder powder 112 and disposing the Pb-free solder powder 112 on appropriate positions at which the open pads of the interposer board to be pre-soldered are present, the board is screened with a mask 113 (chip unit portions at which the copper pads are present are opened).

In the case in which pre-soldering is performed on the PCB (interposer) having a high density fine pitch and size using a solder dipping or solder printing method according to the related art, an open pad having a significantly small size may not be effectively wetted. However, in the case of using the mask as in the exemplary embodiment of the present invention, the pre-soldering may be effectively performed even on the PCB having a fine pitch and size.

In the present invention, before spraying the Pb-free solder powder 112, in order to allow the Pb-free solder powder 112 to be well wetted at the time of soldering, oil based flux is sprayed by a spray method, and a temperature of the board is raised to an appropriate temperature so that the oil based flux is activated.

Next, the mask 113 is removed, and then the Pb-free solder powder 112 is appropriately wetted on the copper pad 111 through the reflow by raising the temperature to the appropriate temperature, thereby lumping the Pb-free solder powder 112. At this time, the melted solder is formed to thereby fully fill the copper pad 111, and an excess melted solder overflows on a passivation layer of the board.

Then, the hot air flux spray 115 is performed on the lumped Pb-free solder powder 112, thereby removing an unnecessary Pb-free solder powder 112 to planarize the solder. In this case, the solder is planarized with respect to the pre-solder at the same height as each other by adjusting an appropriate thickness of an external passivation limiting a range of the copper pad 111 and a spraying angle at the time of performing the hot air flux spray 115.

The Pb-free solder powder 112 may be ref lowed at a temperature of a melting point of each solder or more.

Hereinafter, Examples of the present invention will be described. The following Examples are only to exemplify the present invention, and the scope of the present invention should not be interpreted to being limited to these Examples.

### INVENTIVE EXAMPLE

Surface treatment of a printed circuit board according to the exemplary embodiment of the present invention was performed according to the process shown in FIG. 1.

First, in the printed circuit board on which a copper circuit was printed, portions at which Cu pads are exposed except for a copper foil layer were screened with a mask.

Then, oil based special flux was sprayed onto the copper foil layer by a spray method so that solder powder was appropriately wetted.

In addition, Pb-solder powder (SnBi, melting point: 138° C.) having a size of one third (60 μm) of a diameter of the open pad was filled in the copper foil layer, and the mask was removed.

The Pb-free solder applied onto the copper foil layer was reflowed at 160° C. for 1 minute or less to allow the Pb-free solder to be well lumped, and the hot air flux spray method was performed on the lumped Pb-free solder to remove the Pb-free solder smeared on a passivation layer simultaneously with planarizing the Pb-free solder, such that the surface treatment of the printed circuit board was performed so as to have the copper foil layer surface treated with the PB-free solder having the same height as that of a solder resist.

### COMPARATIVE EXAMPLE

The surface treatment of the printed circuit board was performed by the same method as in the Inventive Example except that the Pb-free solder is planarized by performing a hot air solder leveling (HASL) method according to the related art instead of performing the hot air flux spray method on the lumped Pb-free solder.

Experimental Example: Measurement of Pattern Size of Surface Treated Printed Circuit Board

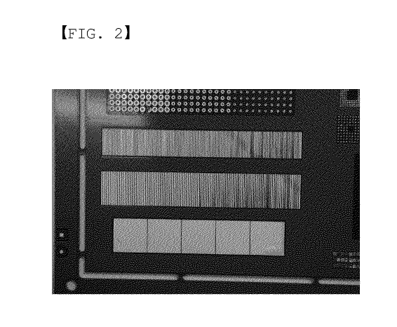

Sizes of copper foil layer pads of the printed circuit boards including the copper foil layers surface treated according to Inventive Example and Comparative Example were measured, and the results were shown in the following Table 1 and FIG. 2.

TABLE 1

| | Size of copper foil layer pad |
|---|---|
| Inventive Example | 200 μm or less |
| Comparative Example | 400 μm or more |

Referring to Table 1 and FIG. 2, in the copper foil layer surface treated by the HAFS method according to the present invention, the pad had a significantly fine size of 200 μm or less, but in the copper foil layer surface treated by the HASL method according to the related art, the pad of the copper layer had a size of 400 μm or more.

Therefore, with the method according to the present invention, the surface treatment of the copper circuit of the printed circuit board may be effectively performed, such that oxidation of the copper wire circuit may be prevented, and connection with the mounted components may be easily performed.

According to the present invention, the surface treatment of the package board or interposer board having an ultra-fine pitch (300 μm or less) may be easily implemented by a cheap process.

In addition, the printed circuit board may be surface treated by the eco-friendly process using the Pb-free solder, and it may be easy to surface treat the package board or interposer board based on the organic material sensitive to a high temperature.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A printed circuit board comprising a copper foil layer surface treated with a Pb-free solder having the same height as that of a solder resist.

2. The printed circuit board according to claim 1, wherein the Pb-free solder contains Sn as a main component and additionally contains at least one kind selected from Bi, In, Ag, Zn, and Cu.

3. The printed circuit board according to claim 2, wherein the Pb-free solder is a low melting point solder having a melting point of 110 to 220° C.

4. The printed circuit board according to claim 1, wherein it is a package board or an interposer board.

5. The printed circuit board according to claim 1, wherein the copper foil layer is a fine pitch copper pad having a pad size of 200 μm or less and a pad pitch of 300 μm or less.

6. A surface treatment method of a printed circuit board, the surface treatment method comprising:
screening an open pad except for a copper foil layer with a mask;
applying Pb-free solder powder onto the copper foil layer;
removing the mask;
lumping the Pb-free solder powder by reflowing the Pb-free solder powder applied onto the copper foil layer; and
planarizing the lumped Pb-free solder powder by a hot air flux spray (HAFS) method.

7. The surface treatment method according to claim 6, wherein the copper foil layer is a fine pitch copper pad having a pad size of 200 μm or less and a pad pitch of 300 μm or less.

8. The surface treatment method according to claim 6, wherein the Pb-free solder powder contains Sn as a main component and additionally contains at least one kind selected from Bi, In, Ag, Zn, and Cu.

9. The surface treatment method according to claim 6, wherein the Pb-free solder is a low melting point solder having a melting point of 110 to 220° C.

10. The surface treatment method according to claim 6, wherein an average particle size of the Pb-free solder powder is a half or less of a diameter of the open pad.

11. The surface treatment method according to claim 6, wherein the ref lowing is performed at a temperature higher than a melting point of the Pb-free solder powder.
